(19) United States
(12) Patent Application Publication
(10) Pub. No.: US 2024/0266108 A1
(43) Pub. Date: Aug. 8, 2024

(54) METHOD FOR PRODUCING ELECTRONIC COMPONENT AND ELECTRONIC COMPONENT

(71) Applicant: TDK Corporation, Tokyo (JP)

(72) Inventors: Youichi KAZUTA, Tokyo (JP); Kazuya TOBITA, Tokyo (JP); Yuto SHIGA, Tokyo (JP); Yuichi TAKUBO, Tokyo (JP); Xuran GUO, Tokyo (JP); So KOBAYASHI, Tokyo (JP); Hiroto KOMATSU, Tokyo (JP); Toru YAGINUMA, Tokyo (JP)

(73) Assignee: TDK Corporation, Tokyo (JP)

(21) Appl. No.: 18/425,517

(22) Filed: Jan. 29, 2024

(30) Foreign Application Priority Data
Feb. 2, 2023 (JP) 2023-014766

(51) Int. Cl. H01F 41/04; H01F 17/00; H01F 17/04; H01F 27/29

(52) U.S. Cl. CPC H01F 41/041; H01F 17/0013; H01F 17/04; H01F 27/292; H01F 2017/048

(57) ABSTRACT

An electronic component includes an element body including a first principal surface and a second principal surface opposing each other, and first and second external electrodes disposed on the first principal surface and separated from each other. The element body includes a first region including the first principal surface and a second region located between the first region and the second principal surface. The first region includes a portion located between the first and second external electrodes. The portion included in the first region is in contact with the first and second external electrodes. When viewed in a direction in which the first principal surface and the second principal surface oppose each other, the portion included in the first region covers an end of each of the first and second external electrodes. The first region has hardness greater than that of the second region.

### CROSS-REFERENCE TO RELATED APPLICATIONS

This application is based upon and claims the benefit of priority from Japanese Patent Application No. 2023-014766, filed on Feb. 2, 2023. The entire contents of which are incorporated herein by reference.

### BACKGROUND

### Field

The present disclosure relates to a method for producing an electronic component and an electronic component.

### Description of the Related Art

Known methods for producing an electronic component include preparing a green sheet including a first surface and a second surface opposing each other, and forming an electrode pattern including a first portion and a second portion separated from each other on the first surface using an electrically conductive paste (for example, refer to International Publication No. 2018/216452). In this producing method, the pair of external electrodes can be formed from the electrode pattern, and an element body can be formed from the green sheet.

### SUMMARY

An object of an aspect of the present disclosure is to provide a method for producing an electronic component in which a plurality of green sheets are appropriately laminated and increasing adhesion between an electrode pattern and a green sheet. An object of another aspect of the present disclosure is to provide an electronic component in which a plurality of green sheets are appropriately laminated and increasing adhesion between an electrode pattern and a green sheet.

A method for producing an electronic component according to one aspect of the present disclosure includes preparing a first green sheet including a first surface and a second surface opposing each other, preparing a second green sheet including a third surface and a fourth surface opposing each other, forming an electrode pattern including first portions and second portions separated from each other on the first surface using an electrically conductive paste, forming an insulating pattern in contact with the first surfaces and the second portions between the first portions and the second portions using an electrically insulating paste, preparing a base on which the first green sheet is to be placed, placing the first green sheet on which the electrode pattern and the insulating pattern are formed on the base such that the first portions, the second portions, and the insulating pattern are in contact with the base, and placing the second green sheet on the first green sheet such that the third surface is in contact with the second surface.

In the one aspect, the first green sheet on which the electrode pattern and the insulating pattern are formed is placed on the base such that the first and second portions included in the electrode pattern and the insulating pattern are in contact with the base. Therefore, when the plurality of green sheets including the first and second green sheets are laminated, a force tends to act on the electrode pattern and the first green sheet in a direction in which the electrode pattern and the first green sheet are brought into close contact with each other. As a result, the adhesion between the electrode pattern and the first green sheet is increased. Similarly, the adhesion between the insulating pattern and the first green sheet is increased.

When the first green sheet is placed on the base, the insulating pattern is in contact with the base. The insulating pattern is in contact with the first surface of the first green sheet and the first and second portions included in the electrode pattern. Therefore, when the plurality of green sheets including the first and second green sheets are laminated, the force tends to act in a direction in which the plurality of green sheets are brought into close contact with each other also in a region corresponding to between the first portion and the second portion of the first green sheet. As a result, the plurality of green sheets are appropriately laminated.

In the one aspect, preparing the first green sheet may include preparing a first green sheet including a first inorganic material. Preparing the second green sheet may include preparing a second green sheet including a second inorganic material different from the first inorganic material. Forming the insulating pattern may include forming the insulating pattern using the electrically insulating paste including the first inorganic material. The first inorganic material may have hardness greater than that of the second inorganic material.

In the case where the first green sheet including the first inorganic material is prepared and the second green sheet including the second inorganic material is prepared, hardness of the first inorganic material may be greater than that of the second inorganic material. When hardness of the first inorganic material is greater than that of the second inorganic material, the electrode pattern may be formed on the first green sheet including the first inorganic material having greater hardness. Therefore, the pair of external electrodes formed from the electrode pattern is reliably connected to the region of an element body formed from the first green sheet.

The one aspect may include preparing a third green sheet including the first inorganic material, and placing the third green sheet on the second green sheet such that the third green sheet is positioned at least at an outermost position of an element body.

When the third green sheet is placed to be located at least at the outermost position, the second green sheet is located between the first and third green sheets. The second green sheet including the second inorganic material is positioned between the first and third green sheets including the first inorganic material having hardness greater than that of the second inorganic material. Therefore, the outermost portion or the lowermost portion of the element body is formed from the third green sheet including the first inorganic material.

Another aspect of the present disclosure includes an element body including a first principal surface and a second principal surface opposing each other, and first and second external electrodes disposed on the first principal surface and separated from each other. The element body includes a first region including the first principal surface and a second region located between the first region and the second principal surface. The first region includes a portion located between the first and second external electrodes. The portion is in contact with the first and second external electrodes. When viewed in a direction in which the first principal surface and the second principal surface oppose each other, the portion included in the first region covers an end of each of the first and second external electrodes. The first region has hardness greater than that of the second region.

In the other aspect, the first region includes a portion located between the first and second external electrodes to be in contact with the first and second external electrodes. The portion of the first region located between the first and second external electrodes covers the end of each of the first and second external electrodes. Since the end of each of the first and second external electrodes is covered with the portion of the first region, the connection strength between the first and second external electrodes and the element body is improved. The first region having hardness greater than that of the second region firmly connects the first and second external electrodes to the element body.

In the other aspect, the element body may include a third region including the second principal surface. The third region may have hardness greater than that of the second region.

In the configuration in which the element body includes the third region including the second principal surface, the second region is located between the first and third regions having hardness greater than that of the second region. The second region is protected by the first and third regions.

The other aspect may include an internal conductor electrically connected to the first and second external electrodes and disposed in the second region.

In the configuration including the internal conductor electrically connected to the first and second external electrodes and disposed in the second region, the second region in which the internal conductor is disposed is located between the first and third regions having hardness greater than that of the second region. The first and third regions protect the inner conductor arranged in the second region.

In the other aspect, the entirety of each of the first and second external electrodes may overlap the first region when viewed in the direction in which the first principal surface and the second principal surface oppose each other.

The configuration in which the entirety of each of the first and second external electrodes overlaps the first region when viewed in the direction in which the first principal surface and the second principal surface oppose each other further improves the connection strength between the first and second external electrodes and the element body.

In the other aspect, each of the first and second external electrodes may include a first electrode surface in contact with the first region and a second electrode surface opposing the first electrode surface. The second electrode surface included in the first external electrode may include a first surface region that includes an end edge opposing the second electrode surface included in the second external electrode in a direction in which the first and second external electrodes are separated from each other and is covered with a portion included in the first region, and a second surface region exposed from the portion included in the first region. The second electrode surface included in the second external electrode may include a first surface region that includes an end edge opposing the second electrode surface included in the first external electrode in a direction in which the first and second external electrodes are separated from each other and is covered with a portion included in the first region, and a second surface region exposed from the portion included in the first region.

In the configuration in which each of the first and second external electrodes includes the first electrode surface in contact with the first region and the second electrode surface, the first and second external electrodes are connected to the first region via the first electrode surface. The first and second external electrodes are connected to the portion of the first region via the first surface region of the second electrode surface. The first and second external electrodes further improve the connection strength with the element body via the first electrode surface and the first surface region. The first and second external electrodes are electrically connected to the electronic device via the second surface region.

In the other aspect, in each of the first and second external electrodes, a length of the second surface region in the intersecting direction that intersects the direction in which the first and second external electrodes are separated from each other may be greater than a length of the first surface region in the intersecting direction.

In the configuration in which the length of the second surface region in the direction intersecting the direction in which the first and second external electrodes are separated from each other is greater than the length of the first surface region in the intersecting direction, the end edge of the element body portion including the first surface region in the intersecting direction is covered with the portion of the first region area of the first electrode surface increases. The increase in the area of the first electrode surface further improves the connection strength between the first and second external electrodes and the element body.

The present disclosure will become more fully understood from the detailed description given hereinafter and the accompanying drawings which are given by way of illustration only, and thus are not to be considered as limiting the present disclosure.

Further scope of applicability of the present disclosure will become apparent from the detailed description given hereinafter. However, it should be understood that the detailed description and specific examples, while indicating examples of the disclosure, are given by way of illustration only, since various changes and modifications within the spirit and scope of the disclosure will become apparent to those skilled in the art from this detailed description.

### BRIEF DESCRIPTION OF THE DRAWINGS

FIG. 1 is a perspective view illustrating an electronic component according to an example;

FIG. 2 is a side view illustrating the electronic component according to the present example;

FIG. 3 is a bottom view illustrating the electronic component according to the present example;

FIG. 4 is an exploded perspective view illustrating the electronic component according to the present example;

FIG. 5 is a diagram illustrating a producing process of the electronic component according to the present example;

FIG. 6 is a view illustrating a producing process of the electronic component according to the present example;

FIG. 7 is a view illustrating a producing process of the electronic component according to the present example;

FIG. 8 is a diagram illustrating a producing process of the electronic component according to the present example; and

FIG. 9 is a view illustrating a producing process of the electronic component according to the present example.

### DETAILED DESCRIPTION

Hereinafter, examples of the present disclosure will be described in detail with reference to the accompanying drawings. In the following description, the same elements or elements having the same functions are denoted with the same reference numerals and overlapped explanation is omitted.

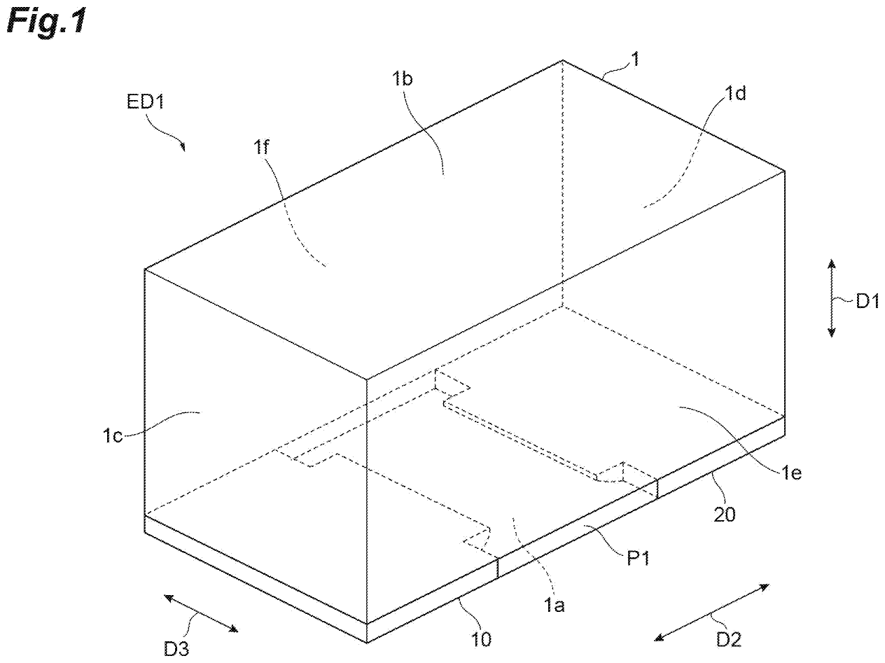

In the present specification, a configuration and a producing method for an electronic component ED1 will be described with reference to FIGS. 1 to 9. The electronic component ED1 includes, for example, a multilayer inductor. For example, the electronic component ED1 is formed of the multilayer inductor.

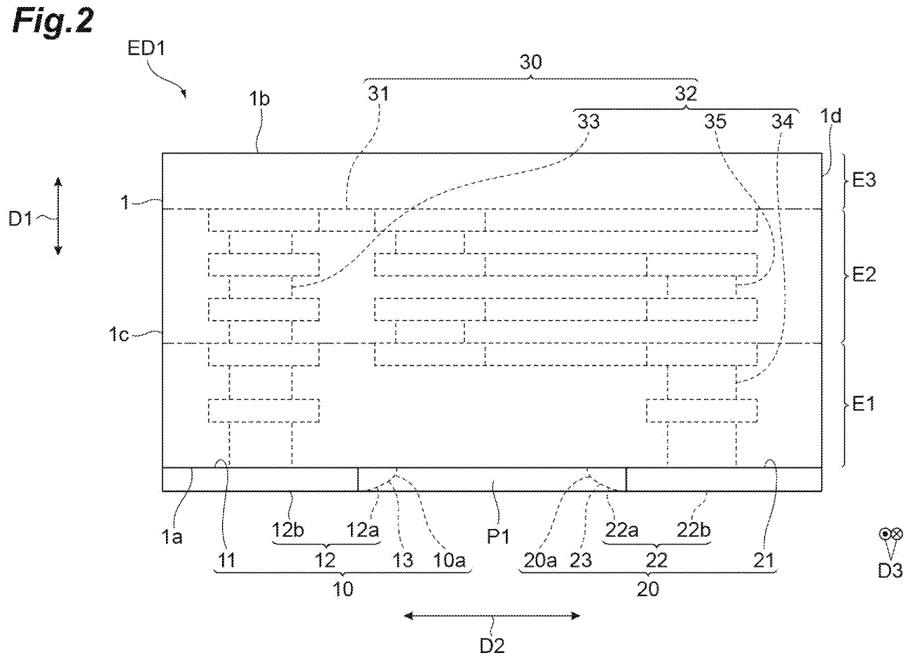

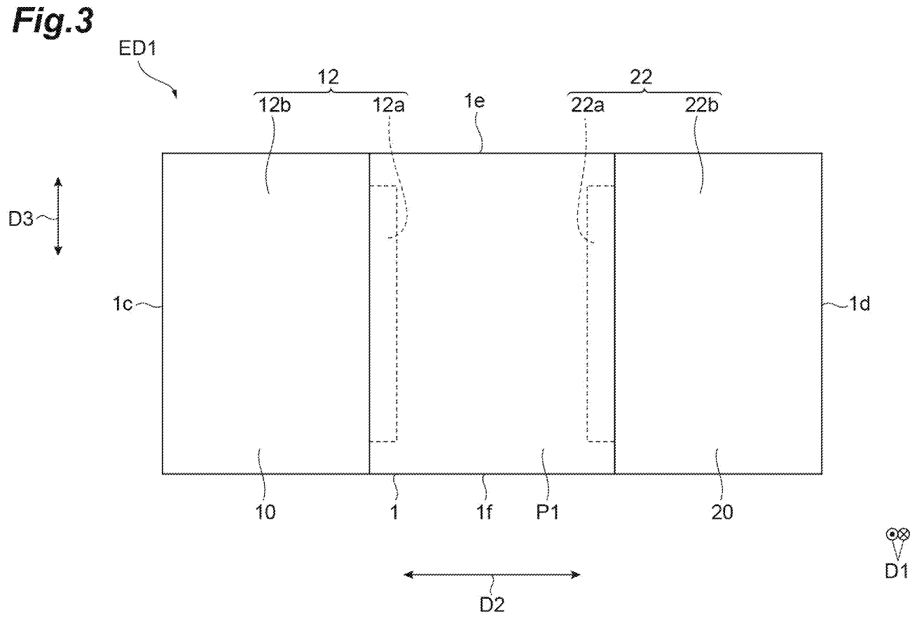

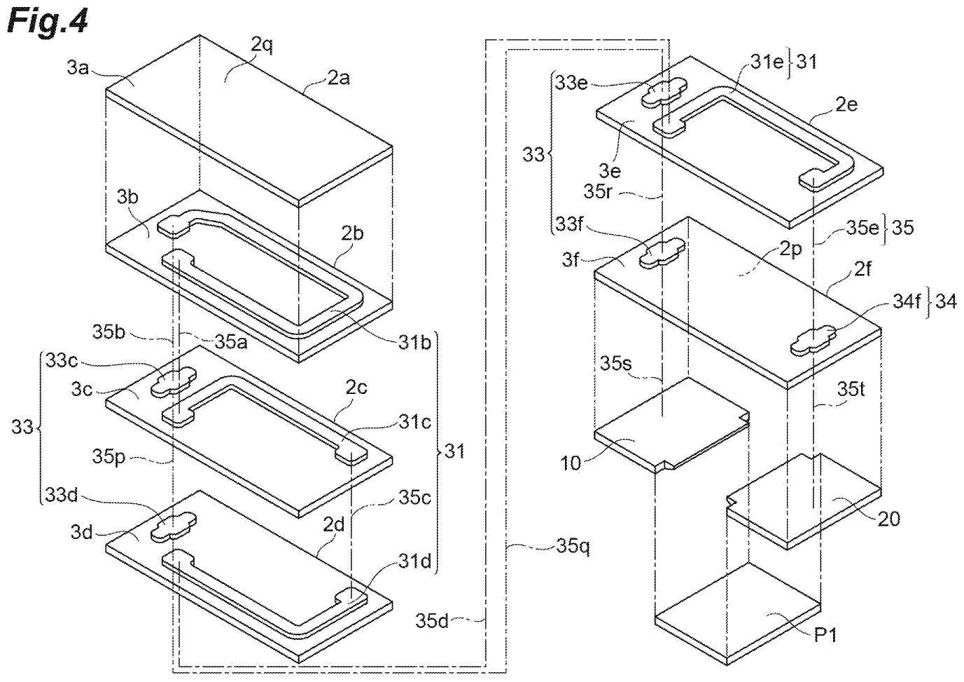

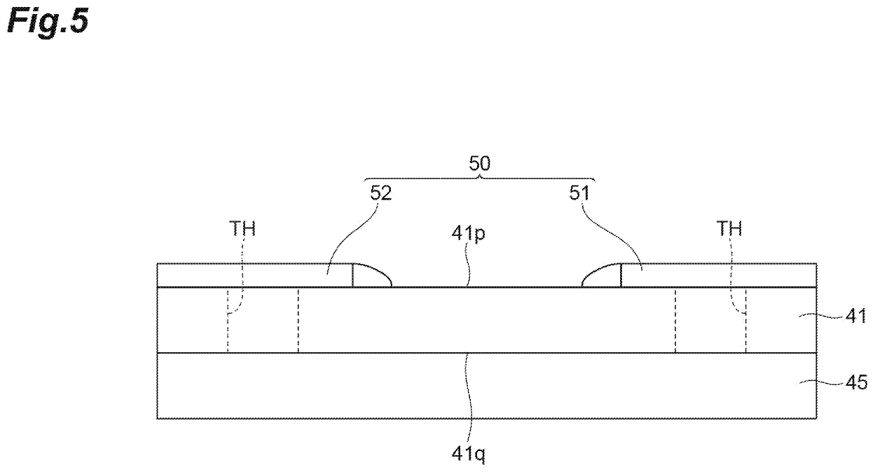

FIG. 1 is a perspective view illustrating an electronic component according to the present example. FIG. 2 is a side view illustrating the electronic component according to the present example. FIG. 3 is a bottom view illustrating the electronic component according to the present example. FIG. 4 is an exploded perspective view illustrating the electronic component according to the present example. FIGS. 5, 6, 7, 8, and 9 are diagrams illustrating a producing process of the electronic component according to the example.

First, the configuration of the electronic component ED1 will be described with reference to FIGS. 1 to 4. The electronic component ED1 includes an element body 1, external electrodes 10 and 20, and an internal conductor 30. The internal conductor 30 is electrically connected to the external electrodes 10 and 20.

As illustrated in FIG. 1, the element body 1 has, for example, a rectangular parallelepiped shape. The element body 1 includes principal surfaces 1a and 1b opposing each other, side surfaces 1c and 1d opposing each other, and side surfaces 1e and 1f opposing each other. The outer surfaces of the element body 1 include principal surfaces 1a and 1b and side surfaces 1c, 1d, 1e, and 1f. In the present example, the principal surface 1a constitutes a mounting surface. When the electronic component ED1 is mounted on an electronic device, the principal surface 1a opposes the electronic device. The electronic device opposing the principal surface 1a includes a circuit board or an electronic component. The principal surface 1b may constitute the mounting surface. The “rectangular parallelepiped shape” in the present specification includes a rectangular parallelepiped shape in which corner portions and ridge portions are chamfered or a rectangular parallelepiped shape in which corner portions and ridge portions are rounded. For example, when the principal surface 1a includes a first principal surface, the principal surface 1b includes a second principal surface.

The principal surfaces 1a and 1b oppose each other in the first direction D1. The principal surfaces 1a and 1b define both ends of the element body 1 in the first direction D1. The side surfaces 1c and 1d oppose each other in the second direction D2. The side surfaces 1c and 1d define both ends of the element body 1 in the second direction D2. The side surfaces 1e and 1f oppose each other in the third direction D3. The side surfaces 1e and 1f define both ends of the element body 1 in the third direction D3. In the present example, the first direction D1, the second direction D2, and the third direction D3 are orthogonal to each other.

The principal surface 1a and the principal surface 1b extend in the second direction D2 to couple the side surface 1c and the side surface 1d. The principal surface 1a and the principal surface 1b extend in the third direction D3 to couple the side surface 1e and the side surface 1f. The side surface 1c and the side surface 1d extend in the first direction D1 to couple the principal surface 1a and the principal surface 1b. The side surface 1c and the side surface 1d extend in the third direction D3 to couple the side surface 1e and the side surface 1f. The side surface 1e and the side surface 1f extend in the first direction D1 to couple the principal surface 1a and the principal surface 1b. The side surface 1e and the side surface 1f extend in the second direction D2 to couple the side surface 1c and the side surface 1d.

The element body 1 is, for example, about 0.2 mm long in the first direction D1. The element body 1 is, for example, about 0.4 mm long in the second direction D2. The element body 1 is, for example, about 0.2 mm long in the third direction D3. In the present example, the second direction D2 is the longitudinal direction of the element body 1.

In the present example, the external electrodes 10 and 20 are disposed on the principal surface 1a. The external electrodes 10 and 20 are separated from each other. The external electrode 10 is disposed closer to the side surface 1c than the external electrode 20. The external electrode 20 is disposed closer to the side surface 1d than the external electrode 10. The external electrode 10 and the external electrode 20 are separated from each other in the second direction D2. The external electrodes 10 and 20 constitute a pair of external electrodes. For example, when the external electrode 10 includes a first external electrode, the external electrode 20 includes a second external electrode.

The external electrodes 10 and 20 include an electrically conductive material. The electrically conductive material includes, for example, Ag, Pd, Au, Pt, Cu, Ni, Al, Mo, Sn, or W. The electrically conductive material may include an Ag—Pd alloy, an Ag—Cu alloy, an Ag—Au alloy, or an Ag—Pt alloy. The external electrodes 10 and 20 include, for example, an Ni plated layer, an Sn plated layer, a Cu plated layer, or an Au plated layer. The external electrodes 10 and 20 include may have a multilayer structure of these plated layers, and may include a Ni plated layer and an Au plated layer formed on the Ni plated layer. The thickness of the external electrodes 10 and 20 is, for example, 5 to 20 μm.

As illustrated in FIG. 2, the element body 1 includes a region E1, a region E2, and a region E3. The region E1 includes the principal surface 1a. The region E3 includes the principal surface 1b. The region E2 is located between the region E1 and the principal surface 1b in the first direction D1. The region E1 includes a portion P1. The portion P1 is located between the external electrode 10 and the external electrode 20 to be in contact with the external electrodes 10 and 20. When viewed in the first direction D1, the portion P1 covers an end 10a of the external electrode 10 and an end 20a of the external electrode 20. The external electrode 10 includes an end 10a. The external electrode 20 includes an end 20a. The end 10a and the end 20a oppose each other across the portion P1 in the second direction D2. When the region E1 includes a first region, the region E2 includes a second region, and the region E3 includes a third region.

As illustrated in FIGS. 2 and 3, the external electrode 10 includes an electrode surface 11 and an electrode surface 12. The electrode surface 11 is in contact with the region E1. The electrode surface 12 opposes the electrode surface 11. The external electrode 20 includes an electrode surface 21 and an electrode surface 22. The electrode surface 21 is in contact with the region E1. The electrode surface 22 opposes the electrode surface 21. For example, when the electrode surface 11 includes a first electrode surface, the electrode surface 12 includes a second electrode surface. For example, when the electrode surface 21 includes a first electrode surface, the electrode surface 22 includes a second electrode surface.

The electrode surface 12 included in the external electrode 10 includes a surface region 12a and a surface region 12b. The surface region 12a includes an edge 13. The end edge 13 opposes the electrode surface 22 included in the external electrode 20 in the second direction D2. The surface region 12a is covered with the portion P1 included in the region E1. The surface region 12b is exposed from the portion P1 included in the region E1. For example, when the surface region 12a includes a first surface region, the surface region 12b includes a second surface region.

The electrode surface 22 included in the external electrode 20 includes a surface region 22a and a surface region 22b. The surface region 22a includes an end edge 23. The end edge 23 opposes the electrode surface 12 included in the external electrode 10 in the second direction D2. The surface region 22a is covered with the portion P1 included in the region E1. The surface region 22b is exposed from the portion P1 included in the region E1. For example, when the surface region 22a includes a first surface region, the surface region 22b includes a second surface region.

The external electrode 10 includes a portion including the surface region 12a and a portion including the surface region 12b. The portion including the surface region 12a and the portion including the surface region 12b have, for example, a rectangular shape when viewed in the first direction D1. The “rectangular shape” in the present specification includes a shape in which each corner is chamfered or a shape in which each corner is rounded. When viewed in the first direction D1, the entire external electrode 10 is located on the region E1. When viewed in the first direction D1, the entire external electrode 10 overlaps the region E1. In the present example, when viewed in the third direction D3, the surface region 12a monotonically approaches the principal surface 1a as the distance from the surface region 12b increases. The portion including the surface region 12a may have a rectangular shape when viewed in the third direction D3. The portion including the surface region 12b has, for example, a rectangular shape when viewed in the third direction D3.

The portion including the surface region 12b includes a pair of edges defining both ends of the portion including the surface region 12b in the third direction D3, and an edge closer to the side surface 1c. The pair of edges defining both ends in the third direction D3 includes an edge closer to the side surface 1e and an edge closer to the side surface 1f. In the portion including the surface region 12b, when viewed in the first direction D1, an edge close to the side surface 1e coincides with the side surface 1e, and an edge close to the side surface 1f coincides with the side surface 1f. In the portion including the surface region 12b, when viewed in the first direction D1, the edge closer to the side surface 1e may not coincide with the side surface 1e, and the edge closer to the side surface 1f may not coincide with the side surface 1f.

The portion including the surface region 12a includes edges defining both ends of the portion including the surface region 12a in the third direction D3. In the portion including the surface region 12a, the edge closer to the side surface 1e is separated from the side surface 1e, and the edge closer to the side surface 1f is separated from the side surface 1f. In the external electrode 10, the surface region 12b in the third direction D3 is longer than the surface region 12a in the third direction D3.

The external electrode 20 includes a portion including the surface region 22a and a portion including the surface region 22b. The portion including the surface region 22a and the portion including the surface region 22b have, for example, a rectangular shape when viewed in the first direction D1. When viewed in the first direction D1, the entire external electrode 20 is disposed in the region E1. When viewed in the first direction D1, the entire external electrode 20 overlaps the region E1. In the present example, when viewed in the third direction D3, the surface region 22a monotonically approaches the principal surface 1a as the distance from the surface region 22b increases. The portion including the surface region 22a may have a rectangular shape when viewed in the third direction D3. The portion including the surface region 22b has, for example, a rectangular shape when viewed in the third direction D3.

The portion including the surface region 22b includes a pair of edges defining both ends of the portion including the surface region 22b in the third direction D3, and an edge closer to the side surface 1d. The pair of edges defining both ends in the third direction D3 includes an edge closer to the side surface 1e and an edge closer to the side surface 1f. In the portion including the surface region 22b, when viewed in the first direction D1, an edge close to the side surface 1e coincides with the side surface 1e, and an edge close to the side surface 1f coincides with the side surface 1f. In the portion including the surface region 22b, when viewed in the first direction D1, the edge closer to the side surface 1e may not coincide with the side surface 1e, and the edge closer to the side surface 1f may not coincide with the side surface 1f.

The portion including the surface region 22a includes edges defining both ends of the portion including the surface region 22a in the third direction D3. In the portion including the surface region 22a, the edge closer to the side surface 1e is separated from the side surface 1e, and the edge closer to the side surface 1f is separated from the side surface 1f. In the external electrode 20, the surface region 22b in the third direction D3 is longer than the surface region 22a in the third direction D3.

As illustrated in FIGS. 2 to 4, the internal conductor 30 is disposed in the element body 1. In the present example, the internal conductor 30 is disposed in the region E2. A portion of the internal conductor 30 is disposed in the region E1. The internal conductor 30 includes a coil portion 31 and a through-hole portion 32. The coil portion 31 includes a plurality of coil conductors 31b to 31e. The coil portion 31 has, for example, a spiral shape. In the present example, the axial direction of the coil portion 31 is the first direction D1. The coil conductors 31b to 31e are disposed to at least partially overlap each other when viewed in the first direction D1. The coil conductors 31b to 31e are separated from the principal surfaces 1a and 1b and the side surfaces 1c, 1d, 1e, and 1f.

The through hole portion 32 includes a through hole conductor 33, a through hole conductor 34, and a through hole conductor 35. The through-hole conductor 33 includes a plurality of through-hole conductor layers 33c to 33f. The through-hole conductor 34 includes a through-hole conductor layer 34f. The through-hole conductor 35 includes through-hole conductors 35a to 35e and 35p to 35t. The plurality of coil conductors 31b to 31e are electrically connected to each other through corresponding through-hole conductors 35a to 35d. The plurality of through-hole conductor layers 33c to 33f are electrically connected to each other through corresponding through-hole conductors 35p to 35r.

The through-hole conductor 33 electrically connects the coil portion 31 and the external electrode 10. The through-hole conductor 33 extends in the first direction D1. An end portion of the through-hole conductor 33 close to the principal surface 1b is connected to one end of the internal conductor 30 close to the principal surface 1b. In the present example, an end portion of the through-hole conductor 33 close to the principal surface 1b is connected to one end of the coil conductor 31b. The through-hole conductor 33 electrically connects the coil conductor 31b and the external electrode 10. The through-hole conductor 33 is disposed closer to the side surface 1c than the coil portion 31 when viewed in the first direction D1.

The through-hole conductor 34 electrically connects the coil portion 31 and the external electrode 20. The through-hole conductor 34 extends in the first direction D1. An end portion of the through-hole conductor 34 close to the principal surface 1b is connected to one end of the internal conductor 30 close to the principal surface 1a. In the present example, an end portion of the through-hole conductor 34 close to the principal surface 1b is connected to one end of the coil conductor 31e. The through-hole conductor 34 electrically connects the coil conductor 31e and the external electrode 20. The through-hole conductor 34 is disposed closer to the side surface 1d than the through-hole conductor 33 when viewed in the first direction D1.

The element body 1 includes a plurality of layers 2a to 2f laminated on each other. In the present example, the plurality of layers 2a to 2f are laminated in the first direction D1. The plurality of layers 2a to 2f are laminated to such an extent that mutual boundaries cannot be visually recognized in practice. The layers 2a to 2f include insulator layers 3a to 3f.

The layer 2a includes the insulator layer 3a. The layer 2a includes the outermost layer of the element body 1. The principal surface 2q of the layer 2a includes the principal surface 1b of the element body 1. The layer 2b includes the insulator layer 3b and the coil conductor 31b disposed in the insulator layer 3b. The layer 2c includes the insulator layer 3c, and the coil conductor 31c and the through-hole conductor layer 33c disposed in the insulator layer 3c. The through-hole conductor 35a and the through-hole conductor 35b are disposed between the layer 2b and the layer 2c. The through-hole conductor 35a connects one end of the coil conductor 31b and one end of the coil conductor 31c. The through-hole conductor 35b connects the other end of the coil conductor 31b and the through-hole conductor layer 33c.

The layer 2d includes an insulator layer 3d, and the coil conductor 31d and the through-hole conductor layer 33d disposed in the insulator layer 3d. The through-hole conductor 35c and the through-hole conductor 35p are disposed between the layer 2c and the layer 2d. The through-hole conductor 35c connects the other end of the coil conductor 31c and one end of the coil conductor 31d. The through-hole conductor 35p connects the through-hole conductor layer 33c and the through-hole conductor layer 33d.

The layer 2e includes the insulator layer 3e, and the coil conductor 31e and the through-hole conductor layer 33e disposed in the insulator layer 3e. The through-hole conductor 35d and the through-hole conductor 35q are disposed between the layer 2d and the layer 2e. The through-hole conductor 35d connects the other end of the coil conductor 31d and one end of the coil conductor 31e. The through-hole conductor 35q connects the through-hole conductor layer 33d and the through-hole conductor layer 33e.

The layer 2f includes the insulator layer 3f, and the through-hole conductor layer 33f and the through-hole conductor layer 34f disposed in the insulator layer 3f. The through-hole conductor 35e and the through-hole conductor 35r are disposed between the layer 2e and the layer 2f. The through-hole conductor 35e connects the other end of the coil conductor 31e and the through-hole conductor layer 34f. The through-hole conductor 35r connects the through-hole conductor layer 33e and the through-hole conductor layer 33f. The layer 2f includes the lowermost layer of the element body 1. The principal surface 2q of the layer 2f includes the principal surface 1a of the element body 1. The external electrodes 10 and 20 are disposed in the layer 2f. The portion P1 is located between the external electrode 10 and the external electrode 20 in the second direction D2.

The through-hole conductor 35s is disposed between the layer 2f and the external electrode 10. The through-hole conductor 35t is disposed between the layer 2f and the external electrode 20. The through-hole conductor 35s connects the through-hole conductor layer 33f and the external electrode 10. The through-hole conductor 35t connects the through-hole conductor layer 34f and the external electrode 20. In the present example, the layer 2f may include two layers laminated in the first direction D1. In a configuration in which the layer 2f includes two layers, the through-hole conductor layer is disposed between the two layers. The through hole conductor 35s connects the through hole conductor layer 33f and the external electrode 10 via the through hole conductor layer disposed between the two layers. The through hole conductor 35t connects the through hole conductor layer 34f and the external electrode 20 via the through hole conductor layer disposed between the two layers.

In the element body 1, the insulating material including in each of the insulator layer 3a, the insulator layers 3b to 3e, and the insulator layer 3f is different from each other. In the present example, the region E1 includes the insulator layer 3a, the region E2 includes the insulator layers 3b to 3e, and the region E3 includes the insulator layer 3f. The insulator layer 3a includes a first inorganic material. The insulator layers 3b to 3e include a second inorganic material different from the first inorganic material. The insulator layer 3f includes the first inorganic material. In the present example, the first inorganic has hardness greater than that of the second inorganic material. The insulator layer 3a, the insulator layers 3b to 3e, and the insulator layer 3f may include the first inorganic material. The insulator layer 3a, the insulator layers 3b to 3e, and the insulator layer 3f may include the second inorganic material.

The first inorganic material includes, for example, a Ni—Cu—Zn ferrite material, a Ni—Cu—Zn—Mg ferrite material, or a Ni—Cu ferrite material. The first inorganic material includes, for example, a metal oxide. Metallic oxides include, for example, Al₂O₃, SrO, ZrO₂, or TiO₂. The first inorganic material may include an Fe alloy. The first mineral may include a glass-ceramic material or a dielectric material.

The second inorganic material includes, for example, a Ni—Cu—Zn ferrite material, a Ni—Cu—Zn—Mg ferrite material, or a Ni—Cu ferrite material. The second inorganic material may include an Fe alloy. The second mineral may include a glass-ceramic material or a dielectric material.

The inner conductor 30 includes the electrically conductive material. The electrically conductive material includes, for example, Ag, Pd, Au, Pt, Cu, Ni, Al, Mo, or W. The electrically conductive material includes, for example, an Ag—Pd alloy, an Ag—Cu alloy, an Ag—Au alloy, or an Ag—Pt alloy. The internal conductor 30 includes the same electrically conductive material as the external electrodes 10 and 20. The internal conductor 30 may include the electrically conductive material different from that of the external electrodes 10 and 20.

The region E1 has hardness greater than that of the region E2. The region E3 has hardness greater than that of the region E2. Hardness of each of the regions E1, E2, and E3 is determined by hardness of the insulator layers 3a to 3f included in each of the regions E1, E2, and E3. Hardness of each of the regions E1, E2, and E3 is an indicator indicating the mechanical strength of each of the regions E1, E2, and E3.

Hardness of each of the regions E1, E2, and E3 is obtained through, for example, a test using a test blade. The test blade includes, for example, stainless steel with a double-sided cutting edge. When hardness of the region E1 is obtained through a test using the test blade, the element body 1 is cut in the direction perpendicular to the first direction D1, and a cut surface in the region E1 is exposed. The test blade is pressed against the cut surface in the exposed region E1 in a first direction D1 to break the region E1. In this example, the force required to break the region E1 is measured in Newtons. When hardness of each of the regions E2 and E3 is obtained through the test using the test blade, the cut surfaces in the regions E2 and E3 are exposed. According to the same procedure as in the case of the region E1, the forces required to break the regions E2 and E3 are measured. The test blade may include a diamond cone or a steel ball.

In this example, hardness of each of the regions E1, E2, and E3 is obtained from the result of measuring the force required to break each of the regions E1, E2, and E3. The amount of the force required to break is considered to correlate with the amount of hardness. It is assumed that a region where the force necessary for breaking is large has hardness larger than that of a region where the force necessary for breaking is small. In a case where the force required to break the region E1 is greater than the force required to break the region E2, it is estimated that the region E1 has hardness greater than that of the region E2. In the present example, the test using the test blade is performed a plurality of times on each of the regions E1, E2, and E3. The mean value of a plurality of measurement results is taken as the force required to break the one region E1, E2, E3. The mean value of hardness of the regions E1 and E3 is larger than the mean value of that of the region E2.

Hereinafter, an example of a method for producing the electronic component ED1 will be described with reference to FIGS. 5 to 9. The order of the processes for producing the electronic component ED1 may be changed. FIGS. 5 to 9 show structures obtained by each process of producing one electronic component ED1.

In an example of the method for producing the electronic component ED1, first, the slurry and the base material 45 are prepared. The slurry includes a material obtained by mixing an electrically insulating resin and a solvent. The electrically insulating resin includes, for example, an acrylic resin or a butyral resin. The solvent includes, for example, ethyl carbitol or butyl carbitol. The base material 45 includes, for example, a PET film.

Next, the slurry is applied onto the base material 45 due to, for example, a doctor blade method to prepare a plurality of green sheets. The insulator layers 3a to 3f are formed from a plurality of green sheets applied on the base material 45. The plurality of green sheets applied on the base material 45 include the green sheet 41. The element body 1 is formed from a green sheet 41. For example, the insulator layer 3f is formed from the green sheet 41. The green sheet 41 includes a surface 41p and a surface 41q that oppose each other. For example, when the surface 41p includes a first surface, the surface 41q includes a second surface.

The slurry forming the green sheet 41 includes the first inorganic material. Preparing the green sheet 41 includes preparing a green sheet 41 including the first inorganic material. In the present example, preparing the green sheet 41 includes preparing the green sheet 41 including particles of the first inorganic material. The slurry forming a green sheet 42 includes a second inorganic material. Preparing the green sheet 42 includes preparing the green sheet 42 including the second inorganic material. In the present example, preparing the green sheet 42 includes preparing the green sheet 42 including particles of the second inorganic material.

As illustrated in FIG. 5, through holes TH for forming the through-hole conductors 35s and 35t are formed in the green sheet 41. The through holes TH are formed, for example, due to irradiating the green sheet 41 with laser light.

Next, an electrically conductive paste for forming the external electrodes 10 and 20 is applied to the green sheet 41. In the present example, the electrode pattern 50 is formed on the surface 41p using an electrically conductive paste. External electrodes 10 and 20 is formed from the electrode pattern 50. The electrode pattern 50 includes portions 51 and 52 that are separated from each other. The external electrode 10 is formed from the portion 51. The external electrode 20 is formed from the portion 52. The electrically conductive paste forming the external electrodes 10 and 20 is prepared due to, for example, mixing a glass component, an alkali metal, an organic binder, and an organic solvent with metal powder including Ag particles or Ag—Pd alloy particles. For example, when the portion 51 includes a first portion, the portion 52 includes a second portion.

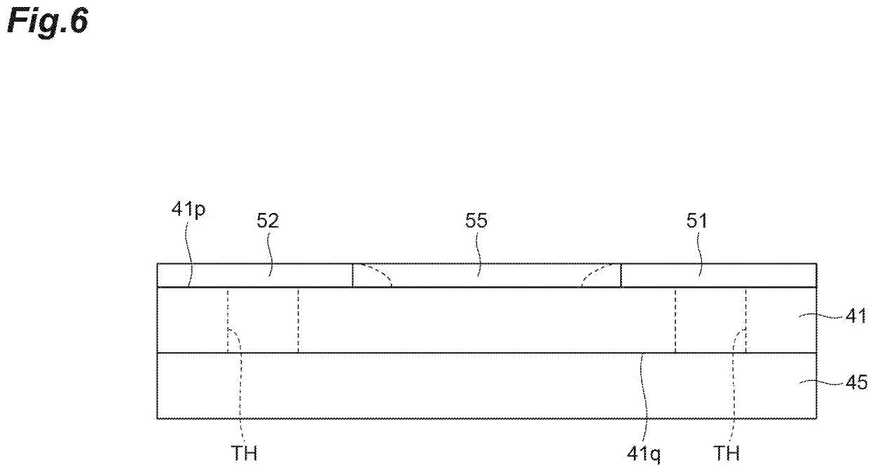

As illustrated in FIG. 6, an electrically insulating paste for forming an insulating pattern 55 is next applied to the green sheet 41. The element body 1 is formed from the insulating pattern 55. In the present example, the insulating pattern 55 is formed using the electrically insulating paste. The insulating pattern 55 is formed between the portion 51 and the portion 52 such that the insulating pattern 55 is in contact with the surface 41p, the portion 51, and the portion 52. The insulating pattern 55 includes the electrically insulating paste including the first inorganic material. Forming the insulating pattern 55 may include forming the insulating pattern 55 due to using the electrically insulating paste that includes the first inorganic material. The electrically insulating paste is applied to the green sheet 41 through a die coater, for example. The insulating pattern 55 is formed due to drying the electrically insulating paste.

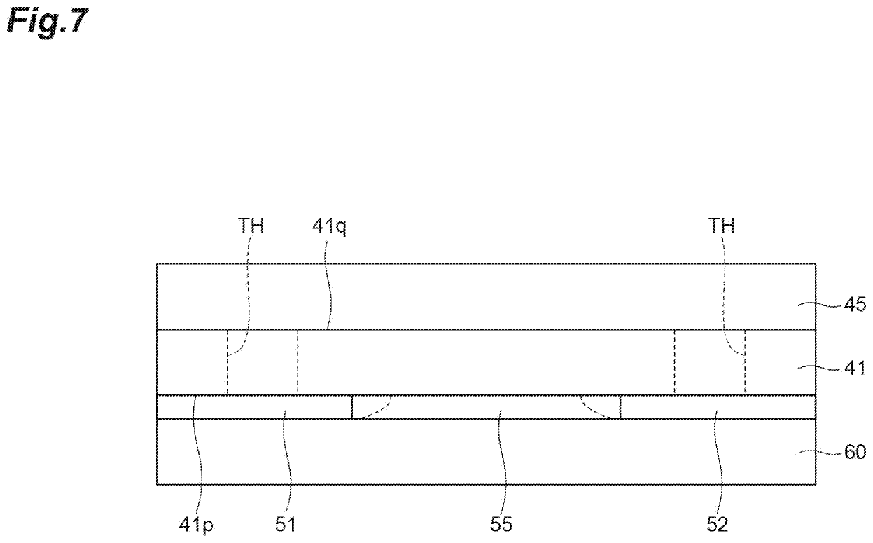

As illustrated in FIG. 7, a base 60 is prepared, and the green sheet 41 is placed on the base 60. The base 60 includes, for example, a polyethylene-based film. In the present example, the green sheet 41 on which the electrode pattern 50 and the insulating pattern 55 are formed is placed on the base 60 such that the portion 51, the portion 52, and the insulating pattern 55 are in contact with the base 60.

The plurality of green sheets applied on the base material 45 include the green sheet 42. The element body 1 is formed from the green sheet 42. For example, the plurality of insulator layers 3b to 3e are formed from the green sheet 42. The green sheet 42 includes a surface 42p and a surface 42q that oppose each other. For example, when the surface 42p includes a third surface, the surface 42q includes a fourth surface.

The green sheet 42 includes a plurality of green sheets 42b, 42c, 42d, and 42e. The green sheet 42b includes a surface 42q. The green sheet 42e includes a surface 42p. The insulator layer 3b is formed from the green sheet 42b. The insulator layer 3c is formed from the green sheet 42c. The insulator layer 3d is formed from the green sheet 42d. The insulator layer 3e is formed from the green sheet 42e. The slurry forming the plurality of green sheets 42b, 42c, 42d, and 42e includes the second inorganic material.

An electrically conductive paste for forming the conductor pattern 58 is applied to the green sheet 42. In the present example, the electrically conductive paste for forming the conductor pattern 58 is applied to each of the plurality of green sheets 42b, 42c, 42d, and 42e. The conductor pattern 58 forms a plurality of coil conductors 31b to 31e. Conductor patterns 58 are formed on a plurality of green sheets 42b, 42c, 42d and 42e with an electrically conductive paste. For example, the conductor pattern 58 that forms the coil conductor 31b is formed on the green sheet 42b. The conductor pattern 58 that forms the coil conductor 31c is formed on the green sheet 42c. The conductor pattern 58 that forms the coil conductor 31d is formed on the green sheet 42d. The conductor pattern 58 that forms the coil conductor 31e is formed on the green sheet 42e. The electrically conductive paste forming the conductor pattern 58 is prepared due to, for example, mixing a glass component, an alkali metal, an organic binder, and an organic solvent with metal powder including Ag particles or Ag—Pd alloy particles.

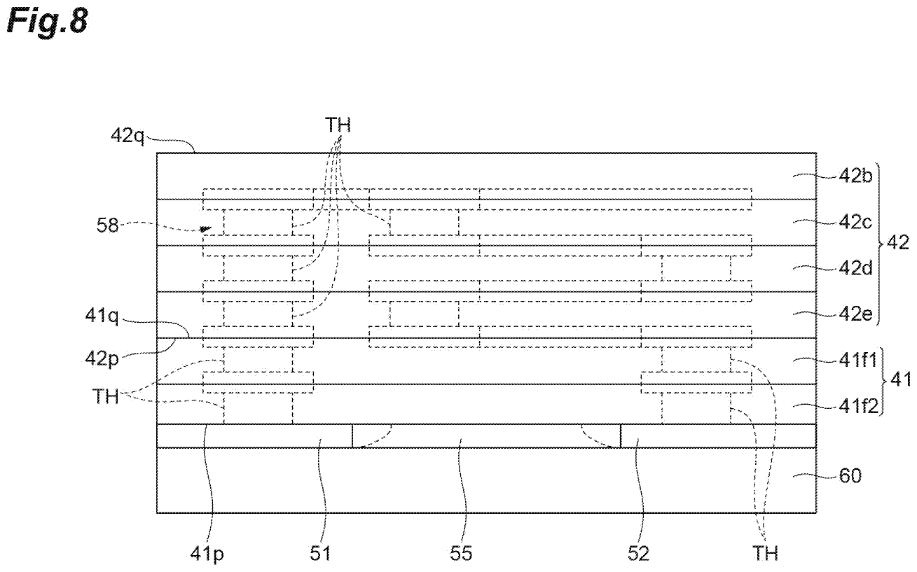

As illustrated in FIG. 8, the base material 45 is peeled off from the green sheet 41, and the green sheet 42 on which the conductor pattern 58 is formed is placed on the green sheet 41. In the present example, the green sheet 42 on which the conductor pattern 58 is formed is placed on the green sheet 41 such that the surface 42p is in contact with the surface 41q. The green sheet 42 is placed on the green sheet 41 in a state where the green sheet 41 is disposed on the base 60. In the present example, the green sheet 42e may be first disposed on the green sheet 41, and then the green sheet 42d may be disposed on the green sheet 42e. Next, the green sheet 42c may be disposed on the green sheet 42d, and next, the green sheet 42b may be disposed on the green sheet 42c.

In the present example, the green sheet 42c is irradiated with laser light to form the through holes TH. The through hole TH formed in the green sheet 42c includes a through hole TH forming the through hole conductor 35a and a through hole TH forming the through hole conductor 35b. The green sheet 42d is irradiated with laser light to form a through hole TH. The through hole TH formed in the green sheet 42d includes a through hole TH forming the through hole conductor 35c and a through hole TH forming the through hole conductor 35p. The green sheet 42e is irradiated with laser light to form a through hole TH. The through hole TH formed in the green sheet 42e includes a through hole TH forming the through hole conductor 35d and a through hole TH forming the through hole conductor 35q.

The green sheet 41 may include a plurality of green sheets 41f1 and 41f2. In each of the plurality of green sheets 41f1 and 41f2, a through hole TH for forming a conductor electrically connecting the conductor pattern 58 and the electrode pattern 50 is formed. The through-hole TH formed in the green sheet 41f1 includes through-holes TH forming through-hole conductors 35e and 35r. The through holes TH formed in the green sheet 41f2 include through holes forming the through-hole conductors 35s and 35t. The through holes TH formed in the green sheets 41 and 42 are filled with the electrically conductive paste. The electrically conductive paste filled in the through holes TH is prepared due to mixing a glass component, an alkali metal, an organic binder, and an organic solvent with metal powder including Ag particles or Ag—Pd alloy particles, for example.

The plurality of green sheets applied on the base material 45 include a green sheet 43. The green sheet 43 includes, for example, one green sheet. An example of the method for producing the electronic component ED1 includes preparing the green sheet 43 including the first inorganic material. The element body 1 is also formed from the green sheet 43. For example, the insulator layer 3a is formed from the green sheet 43. For example, when the green sheet 41 includes a first green sheet, the green sheet 42 includes a second green sheet, and the green sheet 43 includes a third green sheet.

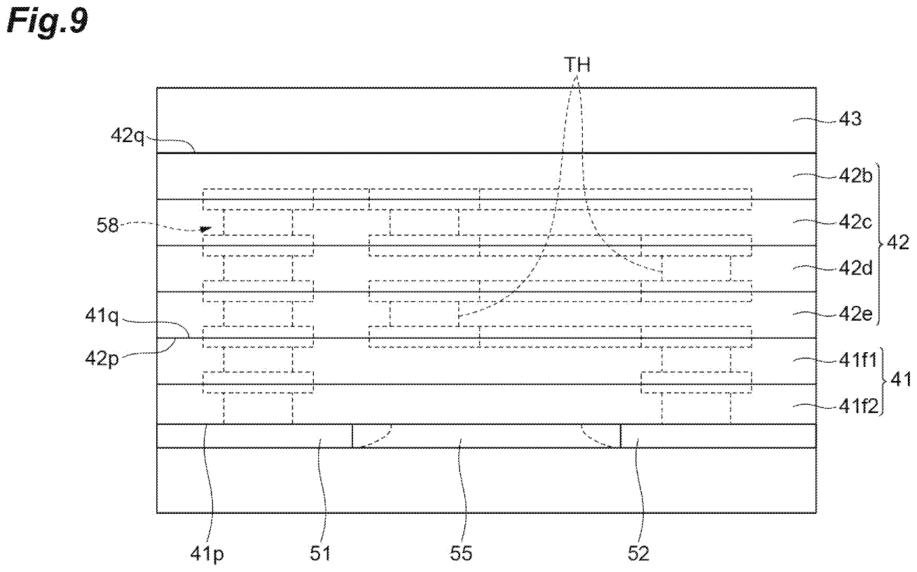

As illustrated in FIG. 9, the green sheet 43 is placed on the green sheet 42. The green sheet 43 is placed on the green sheet 42 such that the green sheet 43 is in contact with the surface 42q.

The laminated green sheets 41, 42 and 43 are pressed in the first direction D1 in which they are laminated. After the laminated green sheets 41, 42 and 43 are pressed, a multilayer body in which the conductor patterns 58 forming the coil conductors 31b to 31e overlap each other when viewed in the first direction D1 is formed. In the present example, the multilayer body includes a plurality of portions for forming the element bodies 1. The multilayer body is cut into a predetermined size using, for example, a cutting machine to cut the multilayer body into a plurality of green chips. The plurality of green chips having a predetermined size are obtained. The electronic component ED1 is made due to sintering the green chip. In the present example, plated layers may be formed on the external electrodes 10 and 20 through a plating method. The plated layer includes, for example, a Ni plated layer and a Sn plated layer.

The first inorganic material has hardness greater than that of the second inorganic material. Hardness of the first and second inorganic materials is an index indicating the mechanical strength of the particles of the first and second inorganic materials, respectively. Hardness of the first and second inorganic materials is determined through, for example, a nanoindentation test.

In the nanoindentation test, a triangular pyramid indenter having a minute size is driven into the particles of the first inorganic material included in the slurry for forming green sheets 41 and 43. A triangular pyramid indenter of a minute size is also driven into the particles of the second inorganic material included in the slurry forming the green sheet 42. The depth of the tip of the triangular pyramid indenter driven into the particles of the first and second inorganic materials is measured. Hardness of the particles of the first and second inorganic materials is obtained from the measurement results of the respective depths into which the tip of the triangular pyramid indenter is driven.

In the present example, the nanoindentation test is performed a plurality of times on each of the slurries forming the green sheet 41, 42, and 43, and the average value of the plurality of measurement results is taken as hardness of the particles of the first and second inorganic materials. The average value of hardness of the particles of the first inorganic material included in the slurry forming the green sheets 41 and 43 is larger than the average value of hardness of the particles of the second inorganic material included in the slurry forming the green sheet 42.

As described above, the method for producing the electronic component ED1 includes preparing the first green sheet including the surfaces 41p and 41q opposing each other, preparing the second green sheet including the surfaces 42p and 42q opposing each other, forming the electrode pattern 50 including the portions 51 and 52 separated from each other on the surface 41p using an electrically conductive paste, forming the insulating pattern 55 in contact with the surface 41p and the portions 51 and 52 between the portions 51 and 52 using the electrically insulating paste, preparing the base 60 on which the first green sheet 41 is to be placed, placing the green sheet 41 on which the electrode pattern 50 and the insulating pattern 55 are formed in contact with the base 60, and placing the green sheet 42, on which the conductor pattern 58 is formed, on the green sheet 41 such that the surface 42p is in contact with the green sheet 41q.

In the method for producing an electronic component ED1, the green sheet 41 on which an electrode pattern 50 and an insulating pattern 55 are formed is placed on a base 60 such that the portions 51 and 52 included in the electrode pattern 50 and the insulating pattern 55 are brought into contact with the base 60. Therefore, when the plurality of green sheets 41 and 42 including the green sheets 41 and 42 are laminated, the force tends to act on the electrode pattern 50 and the green sheet 41 in the direction in which the electrode pattern 50 and the green sheet 41 are brought into close contact with each other. As a result, the adhesion between the electrode pattern 50 and the green sheet 41 is increased. Similarly, the adhesion between the insulating pattern 55 and the green sheet 41 is increased.

When the green sheet 41 is placed on the base 60, the insulating pattern 55 contacts the base 60. The insulating pattern 55 is in contact with the surface 41p of the green sheet 41 and the portions 51 and 52 included in the electrode pattern 50. Therefore, when the plurality of green sheets 41 and 42 including the green sheets 41 and 42 are laminated, the force tends to act in the direction in which the plurality of green sheets 41 and 42 are brought into close contact with each other also in a region corresponding to a portion between the portion 51 and the portion 52 of the green sheet 41. As a result, the plurality of green sheets 41 and 42 are appropriately laminated.

In the present example, the area ratio of the electrode pattern 50 to the green sheet 41 is, for example, 40% or more. Even when the area ratio is 40% or more, the adhesion between the electrode pattern 50 and the insulating pattern 55 and the green sheet 41 is increased. Therefore, a gap tends not to occur between the electrode pattern 50 and the green sheet 41. The area ratio of the electrode pattern 50 to the green sheet 41 may be less than 40%. When the area ratio is less than 40%, the adhesion between the electrode pattern 50 and the insulating pattern 55 and the green sheet 41 is further increased.

In the method for producing the electronic component ED1, preparing the green sheet 41 includes preparing the green sheet 41 including the first inorganic material. Preparing the green sheet 42 includes preparing a green sheet 42 including the second inorganic material different from the first inorganic material. Forming the insulating pattern 55 may include forming the insulating pattern 55 using the electrically insulating paste including the first inorganic material. The first inorganic material has hardness greater than that of the second inorganic material.

When the green sheet 41 including the first inorganic material is prepared and the green sheet 42 including the second inorganic material is prepared, hardness of the first inorganic material is larger than that of the second inorganic material. The electrode pattern 50 is formed on the green sheet 41 including the first inorganic material having high hardness. Therefore, the external electrodes 10 and 20 formed from the electrode pattern 50 is firmly connected to the region of the element body 1 formed from the green sheet 41.

The method for producing the electronic component ED1 includes preparing the green sheet 43 including the first inorganic material, and placing the green sheet 43 on the green sheet 42 such that the green sheet 43 is placed to be located at least at the outermost position of the element body 1.

When the green sheet 43 is placed to be located at least at the outermost position, the green sheet 42 is located between the green sheets 41 and 43. The green sheets 42 including the second inorganic material are disposed between the green sheets 41 and 43 including the first inorganic material having hardness greater than that of the second inorganic material. Therefore, the outermost portion or the lowermost portion of the element body 1 is formed from the green sheet 43 including the first inorganic material.

When a mounting machine mounts the electronic component ED1 on an electronic apparatus, the outermost portion of the element body 1 may come into contact with the mounting machine. In this case, an external force may act on the outermost portion of the element body 1 from the mounting machine. The electronic device includes, for example, a circuit board or an electronic component.

As described above, the outermost portion of the element body 1 is formed of the green sheet 43 including the first inorganic material. Therefore, the outermost portion of the element body 1 has relatively large hardness. As a result, the element body 1 has resistance to the external force.

The electronic component ED1 includes the element body 1 including the principal surface 1a and the principal surface 1b opposing each other, and external electrodes 10 and 20 disposed on the principal surface 1a and separated from each other. The element body 1 includes the region E1 including the principal surface 1a, and the region E2 located between the region E1 and the principal surface 1b. The region E1 includes the portion P1 located between the external electrodes 10 and 20 to be in contact with the external electrodes 10 and 20. The portion P1 is in contact with the external electrodes 10 and 20. When viewed in the first direction D1, the portion included in the region E1 covers the ends 10a and 20a of the external electrodes 10 and 20. The region E1 has hardness greater than that of the region E2.

In the electronic component ED1, the region E1 includes a portion located between the external electrodes 10 and 20 to be in contact with the external electrodes 10 and 20. The portion P1 of the region E1 located between the external electrodes 10 and 20 cover the end 10a of the external electrode 10 and the end 20a of the external electrodes 20. Since the ends 10a and 20a are covered with the portion P1 of the region E1, the connection strength between the external electrodes 10 and 20 and the element body 1 is improved. The region E2 having hardness greater than that of the region E1 reliably connects the external electrodes 10 and 20 and the element body 1.

In the electronic component ED1, the element body 1 includes the region E3 including the principal surface 1b. The region E3 has hardness greater than that of the region E2.

In the configuration in which the element body 1 includes the region E3 including the principal surface 1b, the region E2 is located between the regions E1 and E3 having hardness greater than that of the region E2. The regions E1 and E3 protects the region E2.

The electronic component ED1 includes the internal conductor 30 electrically connected to the external electrodes 10 and 20 and disposed in the region E2.

In the configuration including the internal conductor 30 electrically connected to the external electrodes 10 and 20 and disposed in the region E2, the region E2 in which the internal conductor 30 is disposed is located between the regions E1 and E3 having hardness greater than that of the region E2. The regions E1 and E3 protects the internal conductor 30 disposed in the region E2.

In the electronic component ED1, the entirety of each of the external electrodes 10 and 20 overlaps the region E1 when viewed in the first direction D1.

The configuration in which the entirety of each of the external electrodes 10 and 20 overlaps the region E1 when viewed in the first direction D1 further improves the connection strength between the external electrodes 10 and 20 and the element body 1.

In the electronic component ED1, each of the external electrodes 10 and 20 includes electrode surfaces 11 and 21 in contact with the region E1 and electrode surfaces 12 and 22 opposed to the electrode surface 11 and 21. The electrode surface 12 included in the external electrode 10 includes the end edge 13 opposing the electrode surface 22 included in the external electrode 20 in the direction in which the external electrodes 10 and 20 are separated, and includes the surface region 12a covered with the portion P1 included in the region E1 and the surface region 12b exposed from the portion P1 included in region E1. The electrode surface 22 included in the external electrode 20 includes the end edge 23 opposing the electrode surface 12 included in the external electrode 10 in the direction in which the external electrodes 10 and 20 are separated, and includes the surface region 22a covered with the portion P1 included in the region E1, and the surface region 22b exposed from the portion P1 included in the region E1.

In the configuration in which each of the external electrodes 10 and 20 includes the electrode surfaces 11 and 21, and the electrode surfaces 12 and 22 in contact with the region E1, the external electrodes 10 and 20 is connected to the region E1 via the electrode surfaces 11 and 21. The external electrodes 10 and 20 is connected to the portion P1 in the region E1 via the surface regions 12a and 22a included in the electrode surfaces 12, 22. The external electrodes 10 and 20 further improves the connection strength with the element body 1 via the electrode surfaces 11 and 21 and the surface regions 12a and 22a. The external electrodes 10 and 20 are electrically connected to the electronic device via the surface regions 12b and 22b.

In the electronic component ED1, in each of the external electrodes 10 and 20, the lengths of the surface regions 12b and 22b in the third direction D3 intersecting the direction in which the external electrodes 10 and 20 are separated from each other are greater than the lengths of the surface regions 12a and 22a in the third direction D3.

In the configuration in which the lengths of the surface regions 12b and 22b in the third direction D3 are larger than the lengths of the surface regions 12a and 22a in the third direction D3, the end edge of the element body portion including the surface regions 12a and 22a in the third direction D3 is covered with the portion P1 of the region E1, and thus the areas of the electrode surfaces 11 and 21 increase. The increase in the area of the electrode surfaces 11 and 21 further improves the connection strength between the external electrodes 10 and 20 and the element body 1.

Although the examples of the present disclosure have been described above, the present disclosure is not necessarily limited to the above-described examples, and various modifications can be made without departing from the scope of the present disclosure.

In the electronic component ED1, in each of the external electrodes 10 and 20, the lengths of the surface regions 12b and 22b in the third direction D3 may not be greater than the lengths of the surface regions 12a and 22a in the third direction D3. In the configuration in which the lengths of the surface regions 12b and 22b in the third direction D3 are larger than the lengths of the surface regions 12a and 22a in the third direction D3, as described above, the end edge of the element body portion including the surface regions 12a and 22a in the third direction D3 is covered with the portion P1 of the region E1, and thus the areas of the electrode surfaces 11 and 21 increase. The increase in the area of the electrode surfaces 11 and 21 further improves the connection strength between the external electrodes 10 and 20 and the element body 1.

In the present example, the electronic component ED1 is described as a multilayer inductor, but the electronic component to which the present disclosure can be applied is not limited to the multilayer inductor. Applicable electronic components include, for example, multilayer ceramic capacitors, multilayer varistors, multilayer piezoelectric actuators, multilayer thermistors, and multilayer solid state batteries.

What is claimed is:

1. A method for producing an electronic component comprising:
preparing a first green sheet including a first surface and a second surface opposing each other;
preparing a second green sheet including a third surface and a fourth surface opposing each other;
forming an electrode pattern on the first surface using an electrically conductive paste, the electrode pattern including a first portion and a second portion separated from each other;
forming an insulating pattern between the first portion and the second portion using an electrically insulating paste, the insulating pattern being in contact with the first surface, the first portion, and the second portion;
preparing a base on which the first green sheet is to be placed;
placing the first green sheet on which the electrode pattern and the insulating pattern are formed on the base such that the first portion, the second portion, and the insulating pattern are in contact with the base; and
placing the second green sheet on the first green sheet such that the third surface is in contact with the second surface.

2. The method for producing the electronic component according to claim 1, wherein
preparing the first green sheet includes preparing the first green sheet including a first inorganic material,
preparing the second green sheet includes preparing the second green sheet including a second inorganic material different from the first inorganic material,
forming the insulating pattern includes forming the insulating pattern using the electrically insulating paste including the first inorganic material, and
the first inorganic material has hardness greater than that of the second inorganic material.

3. The method for producing the electronic component according to claim 2 further comprising:
preparing a third green sheet including the first inorganic material; and
placing the third green sheet on the second green sheet such that the third green sheet is located at least at an outermost position of an element body.

4. An electronic component comprising:
an element body including a first principal surface and a second principal surface opposing each other; and
first and second external electrodes disposed on the first principal surface and separated from each other,
wherein the element body includes a first region including the first principal surface and a second region located between the first region and the second principal surface,
the first region includes a portion located between the first and second external electrodes to be in contact with the first and second external electrodes, the portion being in contact with the first and second external electrodes,
the portion included in the first region covers an end of each of the first and second external electrodes when viewed in a direction in which the first principal surface and the second principal surface oppose each other, and
the first region has hardness greater than that of the second region.

5. The electronic component according to claim 4, wherein
the element body further includes a third region including the second principal surface, and
the third region has hardness greater than that of the second region.

6. The electronic component according to claim 4, further comprising:
an internal conductor electrically connected to the first and second external electrodes and disposed in the second region.

7. The electronic component according to claim 4, wherein
when viewed in the direction in which the first principal surface and the second principal surface oppose each other, the entirety of each of the first and second external electrodes overlaps the first region.

8. The electronic component according to claim 4, wherein
each of the first and second external electrodes includes a first electrode surface in contact with the first region and a second electrode surface opposing the first electrode surface,
the second electrode surface included in the first external electrode includes:
a first surface region including an end edge opposing the second electrode surface included in the second external electrode in a direction in which the first and second external electrodes are separated from each other, the first surface region being covered with the portion included in the first region; and
a second surface region exposed from the portion included in the first region,
the second electrode surface included in the second external electrode includes:
a first surface region including an end edge opposing the second electrode surface included in the first external electrode in the direction in which the first and second external electrodes are separated from each other, the first surface region being covered with the portion included in the first region; and
a second surface region exposed from the portion included in the first region.

9. The electronic component according to claim 8, wherein
in each of the first and second external electrodes, a length of the second surface region in an intersecting direction that intersects the direction in which the first and second external electrodes are separated is greater than a length of the first surface region in the intersecting direction.
